(19) United States
(12) Patent Application Publication
(10) Pub. No.: US 2002/0102834 A1
(43) Pub. Date: Aug. 1, 2002

(54) Method of forming dual damascene structure

(76) Inventor: Tien-Chu Yang, Hsinchu (TW)

Correspondence Address: J.C. Patents, Inc., Suite 114, 1340 Reynolds Ave., Irvine, CA, 92614, US

(21) Appl. No.: 09/828,764

(22) Filed: Apr. 9, 2001

(30) Foreign Application Priority Data
Jan. 29, 2001 (TW) 90101611

(51) Int. Cl. H01L 21/4763

(52) U.S. Cl. 438/618; 438/638; 438/643

(57) ABSTRACT

A method of forming a dual damascene structure. A first low-dielectric-constant dielectric layer, an etching stop layer, a second low-dielectric-constant dielectric layer and a silicon oxynitride layer are sequentially formed over a substrate. A dual damascene slot is formed in the first low-dielectric-constant dielectric layer, and a barrier layer that is formed over the exposed surface of the dual damascene slot and the silicon oxynitride layer. Copper is deposited over the substrate filling the dual damascene slot. A copper chemical-mechanical polishing (Cu CMP) is conducted to remove excess copper material using the barrier layer as a polishing stop layer. A Copper/barrier metal CMP is conducted to remove the barrier layer using the silicon oxynitride as an etching stop layer. An ammonia plasma treatment is performed on the exposed silicon oxynitride, barrier layer and copper on the substrate. Finally, a cap layer is formed over the substrate.

### CROSS-REFERENCE TO RELATED APPLICATION

This application claims the priority benefit of Taiwan application serial no. 90101611, filed Jan. 29, 2001.

### BACKGROUND OF THE INVENTION

1. Field of Invention

The present invention relates to a method of forming a metallic interconnect. More particularly, the present invention relates to a method of forming a dual damascene structure.

2. Description of Related Art

Following the rapid progress in manufacturing techniques, the production of ultra-large scale integrated (ULSI) circuits having a line width smaller than 0.13 μm is possible. To increase the operating speed of such circuits, circuit resistance and capacitance must be reduced as much as possible. Hence, low dielectric constant materials are often used for forming the inter-metallic dielectric layer, and copper is often used for forming interconnects. Yet, low dielectric constant materials generally have some undesirable physical properties such as softness, and thermal instability. Moreover, difficulties in controlling the defects in the copper layer and the low dielectric constant material layer often lead to problems in yield.

FIG. 1 is a schematic cross-sectional diagram showing a conventional dual damascene structure. As shown in FIG. 1, the dual damascene structure includes a substrate 100 having a low dielectric constant dielectric layer 102 thereon. The low dielectric constant dielectric layer 102 has a dual damascene slot 106. A barrier layer 104, and a dual damascene structure 108 are enclosed inside the dual damascene slot 106. Furthermore, a cap layer 112 is formed over the low dielectric constant dielectric layer 102, the dual damascene structure 108, and the exposed barrier layer 104.

In the process of forming a damascene structure inside the slot 106, excess metallic and barrier material outside the dual damascene slot 106 is removed by chemical-mechanical polishing. Minor differences in polishing selectivity between the metallic material, and the dielectric material often leads to a premature exposure of the dielectric layer 102 to polishing slurry. Consequently, some copper particles 110 may be trapped inside the dielectric layer 102. The trapped copper particles 110 are difficult to remove and often lead to potential reliability problems. In addition, cohesive strength between the cap layer 112, and the dielectric layer 102 is normally low. Hence, metallic elements may easily diffuse from the dual damascene structure 108 to neighboring layers via the interface between the cap layer 112, and the dielectric layer 102. Such diffusion often leads to a problem of current leakage between metal lines.

### SUMMARY OF THE INVENTION

Accordingly, one object of the present invention is to provide a method of forming a dual damascene structure capable of lowering leakage current between a conductive lines, thereby improving electron migration resistance and increasing interconnect reliability.

To achieve these and other advantages and in accordance with the purpose of the invention, as embodied and broadly described herein, the invention provides a method of forming a dual damascene structure. The method consists of a first low dielectric constant dielectric layer, an etching stop layer, a second low dielectric constant dielectric layer, and a silicon oxynitride layer that are sequentially formed over a substrate. A dual damascene slot is formed in the first and second low dielectric constant dielectric layer. A barrier layer is formed over the exposed surface of the dual damascene slot, and the silicon oxynitride layer. Copper is deposited over the substrate filling the dual damascene slot. A copper chemical-mechanical polishing (Cu CMP) is conducted to remove excess copper material using the barrier layer as a polishing stop layer. A barrier/metal CMP is conducted to remove the barrier layer using the silicon oxynitride as a polishing stop layer. An ammonia plasma treatment is conducted on the exposed surfaces. Finally, a cap layer is formed over the substrate.

In this invention, a silicon oxynitride layer serves as an anti-reflective coating in photolithography, and a polishing stop layer in chemical-mechanical polishing. The silicon oxynitride layer not only reduces the quantity of trapped copper particles inside the low-dielectric-constant dielectric layer but also increases cohesion between the cap layer and the dielectric layer. Ultimately, electron-migration resistance increases and leakage between metal lines via the dielectric layer decreases, thereby leading to a greater interconnect reliability.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional diagram showing a conventional dual damascene structure; and

FIGS. 2A through 2G are schematic cross-sectional views showing the progression of steps for forming a dual damascene structure in a substrate according to a preferred embodiment of this invention.

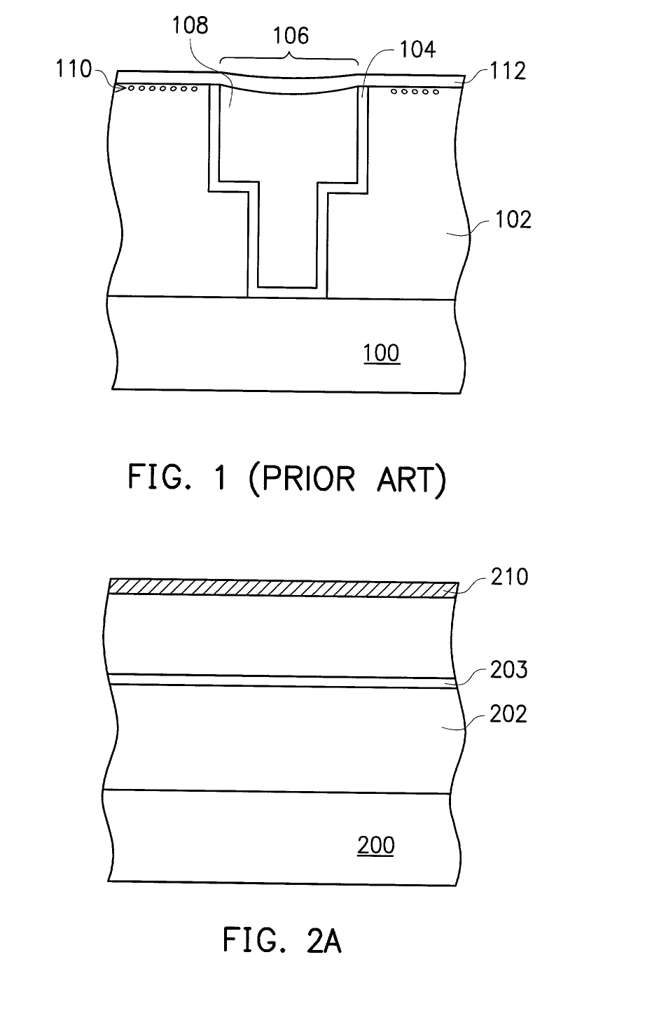

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

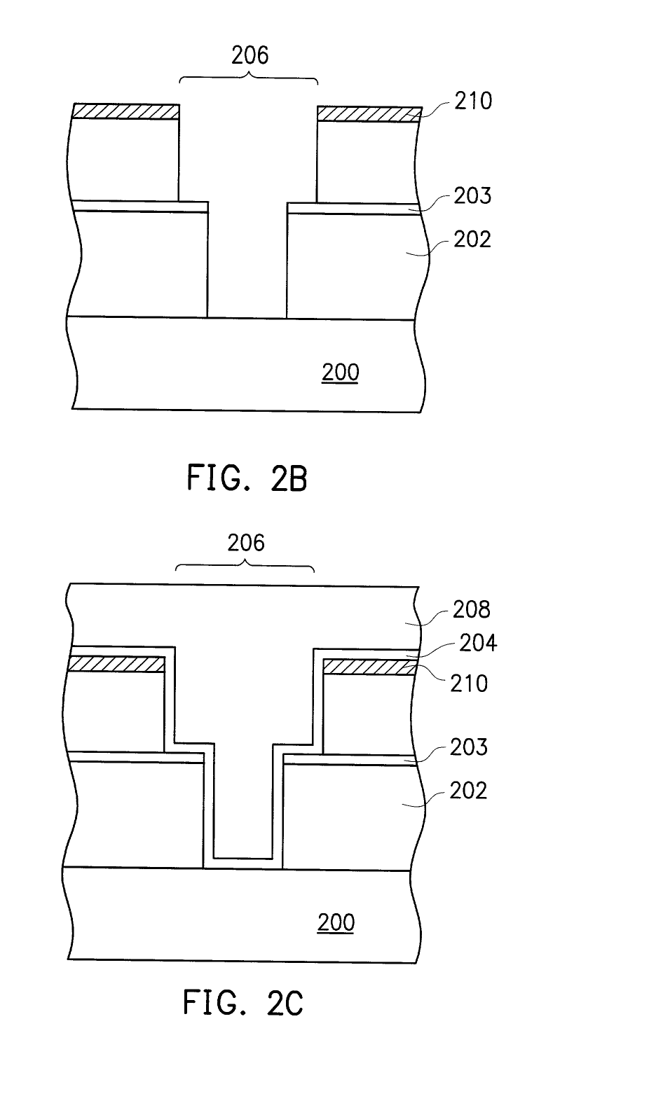

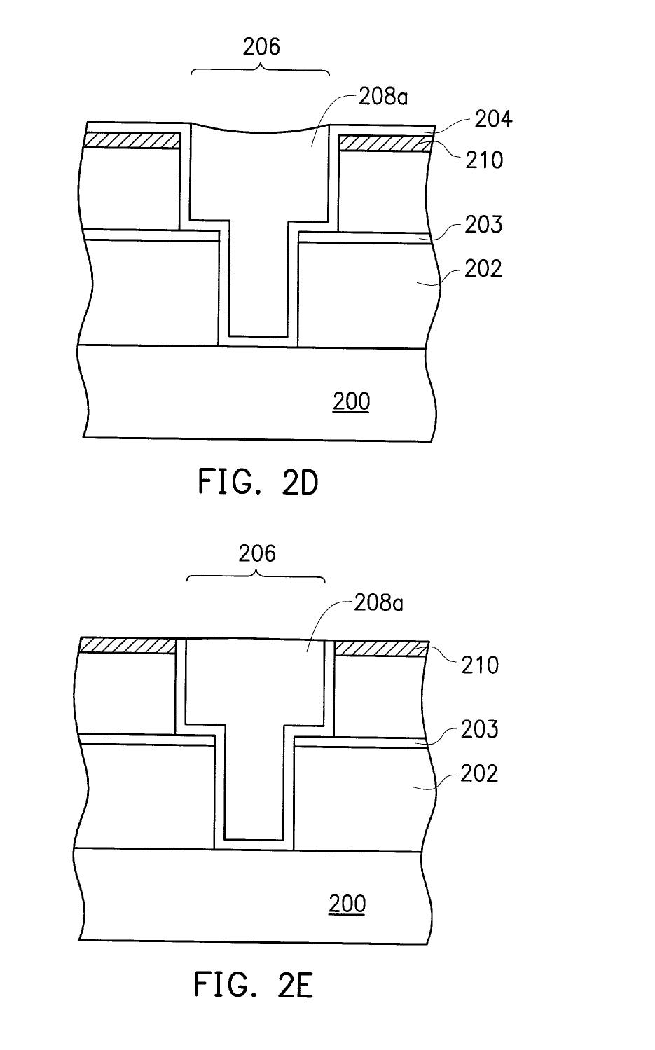

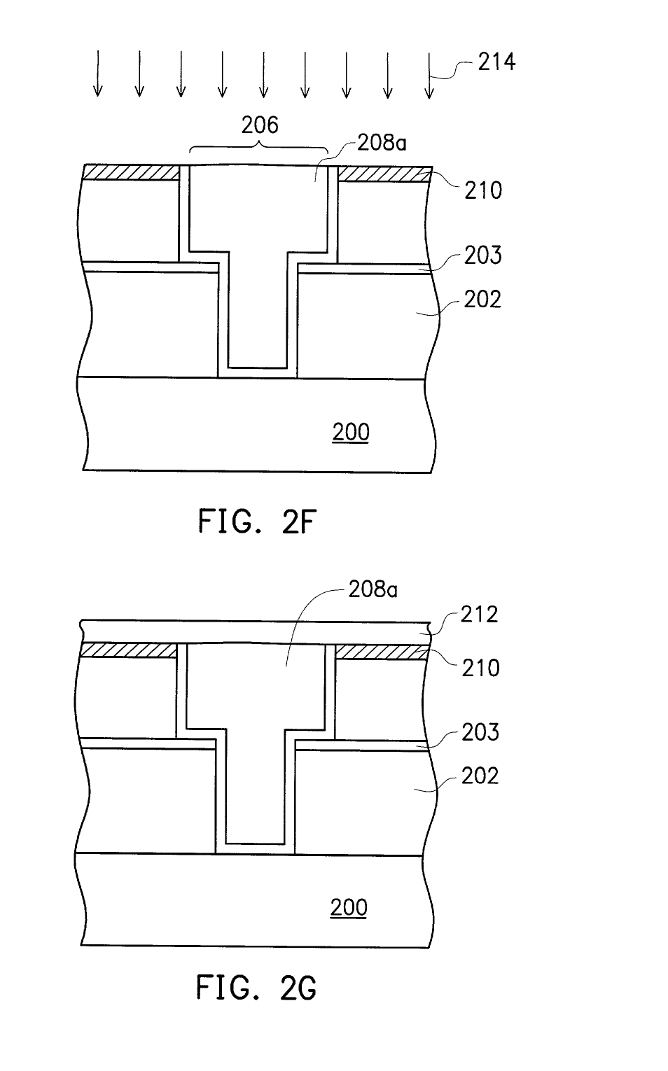

FIGS. 2A through 2G are schematic cross-sectional views showing the progression of steps for forming a dual damascene structure in a substrate according to a preferred embodiment of this invention.

As shown in FIG. 2A, a low-dielectric-constant dielectric layer 202 is formed over a substrate 200. The low-dielectric-constant dielectric layer 202 has an embedded etching stop layer 203. A silicon oxynitride layer 210 is formed over the low-dielectric-constant dielectric layer 202. The dielectric layer 202 can be formed using an organic or an inorganic low dielectric constant material, for example, fluorinated silica glass (FSG). The etching stop layer 203 can be a silicon nitride layer, for example.

As shown in FIG. 2B, a dual damascene slot 206 is formed in the substrate 200. The dual damascene slot 206 is formed in several steps. For example, a photoresist layer (not shown) is formed over the silicon oxynitride layer 210, and the photoresist layer is patterned. Using the patterned photoresist layer as an etching mask, the dielectric layer 202 is etched until a portion of the substrate 200 is exposed to form a via opening. After removing the photoresist layer, another photoresist layer (not shown) is formed over the silicon oxynitride layer 210. The photoresist layer is patterned. Using the patterned photoresist layer as an etching mask, and the etching stop layer 203 as an etching stop, the dielectric layer 202 is etched to form a trench over the via opening.

As shown in FIG. 2C, barrier material is deposited over the exposed surface of the dual damascene slot 206 and the silicon oxynitride layer 210 to form a barrier layer 204. Copper material 208 is deposited over the barrier layer 204 filling the dual damascene slot 206. The barrier layer 204 can be formed from a material such as tantalum nitride, titanium nitride or titanium-silicon nitride.

As shown in FIG. 2D, a copper chemical-mechanical polishing (Cu CMP) is conducted using the barrier layer 204 as a polishing stop layer to remove excess copper material outside the dual damascene slot 206.

As shown in FIG. 2E, another chemical-mechanical polishing of the copper layer 208 and the barrier layer 204 is carried out using the silicon oxynitride layer 210 as a polishing stop layer to remove the barrier layer 204.

As shown in FIG. 2F, an ammonia plasma treatment 214 of the dual damascene structure 208a is conducted. Ultimately, a copper nitride (CuN) layer is formed over the exposed copper layer 208 so that oxidation of copper into oxide material is prevented.

Finally, as shown in FIG. 2G, a cap layer 212 is formed over the substrate 200. The cap layer 212 can be for example a silicon nitride or silicon oxynitride layer.

In aforementioned method of removing the barrier layer 204, polishing selectivity ratio between the barrier layer 204 and the silicon oxynitride layer 210 can be suitably adjusted to prevent the over-polishing of the silicon oxynitride layer 210. Consequently, the low dielectric constant dielectric layer 202 is prevented from exposure to polishing slurry. The presence of the silicon oxynitride layer 210 prevents the infiltration of copper particles into the dielectric layer 202. In addition, the silicon oxynitride layer 210 also serves as an intermediate layer between the dielectric layer 202 and the cap layer 212 so that strong cohesion between the two layers is maintained.

In summary, major aspects of this invention includes:

1. A silicon oxynitride layer is formed over the low-dielectric-constant dielectric layer serving as an anti-reflection coating in a photolithographic process. In addition, the silicon oxynitride layer is retained after the formation of a dual damascene structure above the dielectric layer. Hence, CMP slurry directly contact with the low-dielectric-constant dielectric layer and subsequent trapping of copper particles in the dielectric layer is prevented. Therefore, the substrate can be easily cleaned, and interconnect leakage can be minimized.

2. The silicon oxynitride layer in this invention also serves as a polishing stop layer in chemical-mechanical polishing preventing any direct contact between the subsequently formed cap layer and the polished low dielectric constant dielectric layer. Hence, cohesive strength between the cap layer and the dielectric layer is increased. By preventing the out-diffusion of copper elements from the copper layer to neighboring layers via the interface between the cap layer and the dielectric layer, this invention reduces conductive line leakage and minimizes the electron-migration problem in a copper line.

3. A copper chemical-mechanical polishing is conducted to remove excess copper outside the dual damascene slot and expose the barrier layer before conducting a chemical-mechanical polishing of the copper layer and the barrier layer to remove the barrier layer. This prevents the removal of large quantities of silicon oxynitride from the silicon oxynitride layer and exposure of the low-dielectric-constant dielectric layer to copper contaminant during a copper/barrier layer polishing of a conventional operation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a dual damascene structure, comprising the steps of:
providing a substrate;
forming a low-dielectric-constant dielectric layer over the substrate;
forming a silicon oxynitride layer over the low-dielectric-constant dielectric layer;
forming a dual damascene slot in the low-dielectric-constant dielectric layer and the silicon oxynitride layer;
forming a barrier over the exposed surface of the dual damascene slot and the exposed surface of the silicon oxynitride layer;
forming a copper layer over the substrate completely filling the dual damascene slot;
performing a copper chemical-mechanical polishing using the barrier layer as a polishing stop layer to form a dual damascene structure;
performing a chemical-mechanical polishing of the copper layer and the barrier layer using the silicon oxynitride layer as a polishing stop layer to remove the barrier layer;
performing an ammonia plasma treatment of the dual damascene structure; and
forming a cap layer over the substrate.

2. The method of claim 1, wherein the step of forming the barrier layer includes depositing titanium-silicon nitride.

3. The method of claim 1, wherein the step of forming the barrier layer includes depositing tantalum nitride.

4. The method of claim 1, wherein the step of forming the barrier layer includes depositing titanium nitride.

5. The method of claim 1, wherein the step of forming the cap layer over the substrate includes depositing silicon nitride or silicon oxynitride.

6. The method of claim 1, wherein the step of forming the low-dielectric-constant dielectric layer includes depositing organic or inorganic low-dielectric-constant dielectric material.

7. The method of claim 1, wherein the step of forming the low-dielectric-constant dielectric layer includes depositing fluorinated silicon glass.

8. The method of claim 1, wherein the low-dielectric-constant dielectric layer further includes an embedded etching stop layer.

9. The method of claim 7, wherein the etching stop layer includes a silicon nitride layer.

10. The method of claim 7, wherein the step of forming the dual damascene slot further includes the sub-steps of:
forming a first photoresist layer over the silicon oxynitride layer;
patterning the first photoresist layer;
etching using the first photoresist layer as a mask until the substrate is exposed to form a via opening in the low dielectric constant dielectric layer;
removing the first photoresist layer;
forming a second photoresist layer over the silicon oxynitride layer;
patterning the second photoresist layer; and
etching using the second photoresist layer as a mask and the etching stop layer as an etching stop to form a trench above the via opening.

11. A method of forming a dual damascene structure, comprising the steps of:
providing a substrate;
forming a low-dielectric-constant dielectric layer over the substrate;
forming a silicon oxynitride layer over the low-dielectric-constant dielectric layer;
forming a dual damascene slot in the low-dielectric-constant dielectric layer and the silicon oxynitride layer;
forming a barrier over the exposed surface of the dual damascene slot and the exposed surface of the silicon oxynitride layer;
forming a copper layer over the substrate completely filling the dual damascene slot;
performing a copper chemical-mechanical polishing using the barrier layer as a polishing stop layer to form a dual damascene structure; and
performing a chemical-mechanical polishing of the copper layer and the barrier layer using the silicon oxynitride layer as a polishing stop layer to remove the barrier layer.

12. The method of claim 11, wherein the step of forming the barrier layer includes depositing tantalum nitride.

13. The method of claim 11, wherein the step of forming the barrier layer includes depositing titanium nitride.

14. The method of claim 11, wherein the low-dielectric-constant dielectric layer further includes an embedded etching stop layer.

15. The method of claim 14, wherein the etching stop layer includes a silicon nitride layer.

16. The method of claim 14, wherein the step of forming the dual damascene slot further includes the sub-steps of:
forming a first photoresist layer over the silicon oxynitride layer;
patterning the first photoresist layer;
etching using the first photoresist layer as a mask until the substrate is exposed to form a via opening in the low-dielectric-constant dielectric layer;
removing the first photoresist layer;
forming a second photoresist layer over the silicon oxynitride layer;
patterning the second photoresist layer; and
etching using the second photoresist layer as a mask and the etching stop layer as an etching stop to form a trench above the via opening.

17. The method of claim 11, wherein the step of forming the low-dielectric-constant dielectric layer includes depositing organic or inorganic low dielectric constant dielectric material.

18. The method of claim 11, wherein the step of forming the low-dielectric-constant dielectric layer includes depositing fluorinated silicon glass.

19. The method of claim 11, wherein the step of removing the barrier layer further includes the sub-steps of:
performing an ammonia plasma treatment of the dual damascene structure; and
forming a cap layer over the substrate.

20. The method of claim 19, wherein the step of forming the cap layer over the substrate includes depositing silicon nitride or silicon oxynitride.
